(19) United States
(12) Patent Application Publication
(10) Pub. No.: US 2009/0108880 A1
(43) Pub. Date: Apr. 30, 2009

(54) Systems, Circuits and Methods for Extended Range Input Comparison

(75) Inventor: Babak Soltanian, San Jose, CA (US)

Correspondence Address: Hamilton,DeSanctis & Cha (LSI), 8601 W. CROSS DRIVE, F5-301, LITTLETON, CO, 80123, US

(73) Assignee: Agere Systems Inc.

(21) Appl. No.: 11/877,688

(22) Filed: Oct. 24, 2007

(51) Int. Cl. H03F 3/45

(52) U.S. Cl. 327/52

(57) ABSTRACT

Various embodiments of the present invention provide systems and circuits for processing information through comparison of input signals. For example, various embodiments of the present invention provide comparator circuits that include two input stages that each receive a first input and a second input. One of the input stages is sensitive to a difference between the first input and the second input for at least a low common mode, and provides a first output. The other of the input stages is sensitive to a difference between the positive input and the negative input for at least a high common mode, and provides a second output. The comparator circuits further include a regeneration stage that receives the first output and the second output, and provides a comparator output reflecting the difference between the first input and the second input.

### BACKGROUND OF THE INVENTION

The present invention is related to systems, circuits and methods for comparing one input with another input.

Comparators are used extensively in analog circuits and in mixed signal integrated circuits to control a number of different functions. For example, in a mixed signal integrated circuit, an analog differential input signal may be driven into a comparator circuit that provides a digital differential output. Such circuits are typically capable of detecting a small difference in one signal domain, and replicating that as a large difference in another domain.

FIG. 1 shows an exemplary prior art comparator circuit 100 that uses an input stage and a latch stage. The input stage of comparator circuit 100 includes two N-type transistors 130, 132, two P-type transistors 120, 122, and an N-type tail transistor 145. The source of P-type transistor 120 and the source of P-type transistor 122 are electrically coupled to a power source (VDD). The gate of P-type transistor 120 and the gate of P-type transistor 122 are electrically coupled to a clock input 110. The drain of P-type transistor 120 is electrically coupled to the drain of N-type transistor 130, and the drain of P-type transistor 122 is electrically coupled to the drain of N-type transistor 132. The gate of N-type transistor 130 is electrically coupled to a positive input 134 (IN+) and the gate of N-type transistor 132 is electrically coupled to a negative input 136 (N−). The source of N-type transistor 130 and the source of N-type transistor 132 are electrically coupled to the drain of N-type tail transistor 145. The gate of N-type tail transistor 145 is electrically coupled to clock input 110, and the source of N-type tail transistor 145 is electrically coupled to ground. The input stage provides a positive output 124 (OUT+) from the drain of N-type transistor 130, and a negative output 126 (OUT−) from the drain of N-type transistor 132.

The latch stage of comparator circuit 100 includes two differential pairs each including two N-type transistors. A first differential pair includes two N-type transistors 160, 162, and the second differential pair includes two N-type transistors 170, 172. The latch stage further includes two P-type transistors 150, 152, and a P-type tail transistor 140. The source of P-type tail transistor 140 is electrically coupled to the power source (VDD), the gate of P-type tail transistor 140 to an inverted clock driven by an inverting buffer 115. The drain of P-type tail transistor 140 is electrically coupled to the source of P-type transistor 150 and to the source of P-type transistor 152.

The gate of N-type transistor 160 is electrically coupled to negative output 126, and the gate of N-type transistor 172 is electrically coupled to positive output 124. The source of N-type transistor 160, the source of N-type transistor 162, the source of N-type transistor 170 and the source of N-type transistor 172 are electrically coupled to ground. The drain of N-type transistor 160 and the drain of N-type transistor 162 are electrically coupled to the drain of P-type transistor 150. The drain of N-type transistor 170 and the drain of N-type transistor 172 are electrically coupled to the drain of P-type transistor 152. The gate of N-type transistor 162 is electrically coupled to the gate of P-type transistor 150, and the gate of N-type transistor 170 is electrically coupled to the gate of P-type transistor 152. The latch stage provides a positive output 180 (Q+) from the drain of P-type transistor 150, and a negative output 182 (Q−) from the drain of P-type transistor 152. In operation, a first input is applied to positive input 134 and a second input is applied to negative input 136. When clock input 110 is asserted high, the differential between positive input 134 and negative input 136 is reflected as a differential between positive output 124 and negative output 126. The differential between positive output 124 and negative output 126 is regenerated or amplified by the positive feedback of the latch stage. The positive feedback causes a small differential between positive output 124 and negative output 126 to be reflected as an amplified differential between positive output 180 and negative output 182.

Comparator circuit 100 therefore reflects a small difference between positive input 134 and negative input 136 as a substantial difference between positive output 180 and negative output 182. This works reasonably well as long as the common mode of positive input 134 and negative input 136 is relatively high. In particular, the common mode of positive input 134 and negative input 136 must be high enough to assure that N-type transistors 130, 132, 145 can turn on. Where, in contrast, the common mode of positive input 134 and negative input 136 is not high enough to turn N-type transistors 130, 132, 145 on, the difference between positive input 134 and negative input 136 may not be reflected properly as a difference between positive output 124 and negative output 126. As such, the outputs of the latch stage are not necessarily defined by positive input 134 and negative input 136. Thus, while comparator 100 is a reasonable comparison circuit, the operational range thereof is unnecessarily limited and may not allow for full use of the circuit.

Hence, for at least the aforementioned reasons, there exists a need in the art for advanced systems, circuits and methods for comparing inputs.

### BRIEF SUMMARY OF THE INVENTION

The present invention is related to systems, circuits and methods for comparing one input with another input.

Various embodiments of the present invention provide comparator circuits that include two input stages that each receive a first input and a second input. The first input stage is sensitive to a difference between the first input and the second input for at least a low common mode, and provides a first output. The second input stage is sensitive to a difference between the positive input and the negative input for at least a high common mode, and provides a second output. The comparator circuits further include a regeneration stage that receives the first output and the second output, and provides a comparator output reflecting the difference between the first input and the second input. In some instances of the aforementioned embodiments, the first input stage includes a differential pair of P-type transistors. In such instances, the first input is electrically coupled to the gate of one of the P-type transistors of the differential pair and the second input is electrically coupled to the gate of another of the P-type transistors of the differential pair. In some instances of the aforementioned embodiments, the first input stage includes a differential pair of N-type transistors. In such instances, the first input is electrically coupled to the gate of one of the N-type transistors of the differential pair and the second input is electrically coupled to the gate of another of the N-type transistors of the differential pair.

In a particular instance of the aforementioned embodiments, the second input stage includes: a first, a second and a third N-type transistor; and a first and a second P-type transistor. In such instances, the gate of the first P-type transistor, the gate of the second P-type transistor, and the gate of the third N-type transistor are electrically coupled to a clock signal. The drain of the first P-type transistor is electrically coupled to the drain of the first N-type transistor and the drain of the second P-type transistor is electrically coupled to the drain of the second N-type transistor. The gate of the first N-type transistor is electrically coupled to the first input and the gate of second N-type transistor is electrically coupled to the second input. The source of the first N-type transistor and the source of the second N-type transistor are electrically coupled to the drain of the third N-type transistor. The source of the third N-type transistor is electrically coupled to a lower rail, and the source of the first P-type transistor and the source of the second P-type transistor are electrically coupled to an upper rail. The second output includes a second positive output electrically coupled to the drain of the first P-type transistor and a second negative output electrically coupled to the drain of the second P-type transistor.

The first input stage includes: a first and a second N-type transistor; and a first, a second, and a third P-type transistor. In such instances, the gate of the first N-type transistor, the gate of the second N-type transistor, and the gate of the third P-type transistor are electrically coupled to an inverted version of the clock signal. The drain of the first N-type transistor is electrically coupled to the drain of the first P-type transistor and the drain of the second N-type transistor is electrically coupled to the drain of the second P-type transistor. The gate of the first P-type transistor is electrically coupled to the first input and the gate of second P-type transistor is electrically coupled to the second input. The source of the first P-type transistor and the source of the second P-type transistor are electrically coupled to the drain of the third P-type transistor. The source of the third P-type transistor is electrically coupled to the upper rail, and the source of the first N-type transistor and the source of the second N-type transistor are electrically coupled to the lower rail. The first output includes a first positive output electrically coupled to the drain of the first P-type transistor and a first negative output electrically coupled to the drain of the second P-type transistor.

The regeneration stage includes a first, second, third and fourth N-type transistors; and a first, second, third and fourth P-type transistors. The gate of the first P-type transistor is electrically coupled to the first negative output, and the gate of the fourth P-type transistor is electrically coupled to the first positive output. The gate of the first N-type transistor is electrically coupled to the second negative output, the gate of the fourth N-type transistor is electrically coupled to the second positive output, the gate of the second P-type transistor is electrically coupled to the gate of the second N-type transistor, and the gate of the third P-type transistor is electrically coupled to the gate of the third N-type transistor. The drains of the first P-type transistor and the second P-type transistor are electrically coupled to the drains of the first N-type transistor and the second N-type transistor, and the drains of the third P-type transistor and the fourth P-type transistor are electrically coupled to the drains of the third N-type transistor and the fourth N-type transistor. The comparator output is electrically coupled to the gate of the second P-type transistor and the drain of the third P-type transistor, and/or the gate of the third P-type transistor and the drain of the second P-type transistor.

Other embodiments of the present invention provide mixed signal integrated circuits. Such mixed signal integrated circuits include a differential analog signal with a first signal and a second signal, and a multiple input stage comparator. The multiple input stage comparator includes a first input stage, a second input stage, and a regeneration stage. The first input stage receives the first signal and the second signal and is sensitive to a difference between the first signal and the second signal for at least a low common mode. The first input stage provides a first positive output and a first negative output. The second input stage receives the positive input and the negative input and is sensitive to a difference between the positive input and the negative input for at least a high common mode. The second input stage provides a second positive output and a second negative output. The regeneration stage receives the first positive output, the first negative output, the second positive output and the second negative output. The regeneration stage is operable to provide a comparator output reflecting a relative difference of the first signal and the second signal.

In one particular instance of the aforementioned embodiments, the comparator output includes a positive comparator output and a negative comparator output. In such instances, the positive comparator output and the negative comparator output may toggle as digital signals from rail to rail. Thus, for example, where the positive output is at an upper rail, the negative output may be at a lower rail. Alternatively, where the positive output is at a lower rail, the negative output may be at an upper rail. In some cases, the upper rail is VDD and the lower rail is ground.

Yet other embodiments of the present invention provide electronic devices including a circuit for performing an electronic function. The circuit may include one or more multiple input stage comparator circuits in accordance with different embodiments of the present invention. In some cases, an input of the aforementioned comparator circuits is an analog input, and the output is a digital output. Such electronic devices may include, but are not limited to, a communication device, a hard disk drive, an audio player, a video player. Further, such electronic function may include, but is not limited to, a communication function, a data storage function, an audio record function, an audio play function, a video record function, or a video play function.

This summary provides only a general outline of some embodiments of the invention. Many other objects, features, advantages and other embodiments of the invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several drawings to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 is a prior art comparator circuit;

FIG. 2 depicts a comparator system exhibiting an extended input range in accordance with one or more embodiments of the present invention;

FIGS. 3a-3c are timing diagrams showing the operation of the comparator system of FIG. 2 for a high common mode input, a low common mode input, and an average common mode input; and

FIG. 4 depicts an extended range comparator circuit in accordance with various embodiments of the present invention.

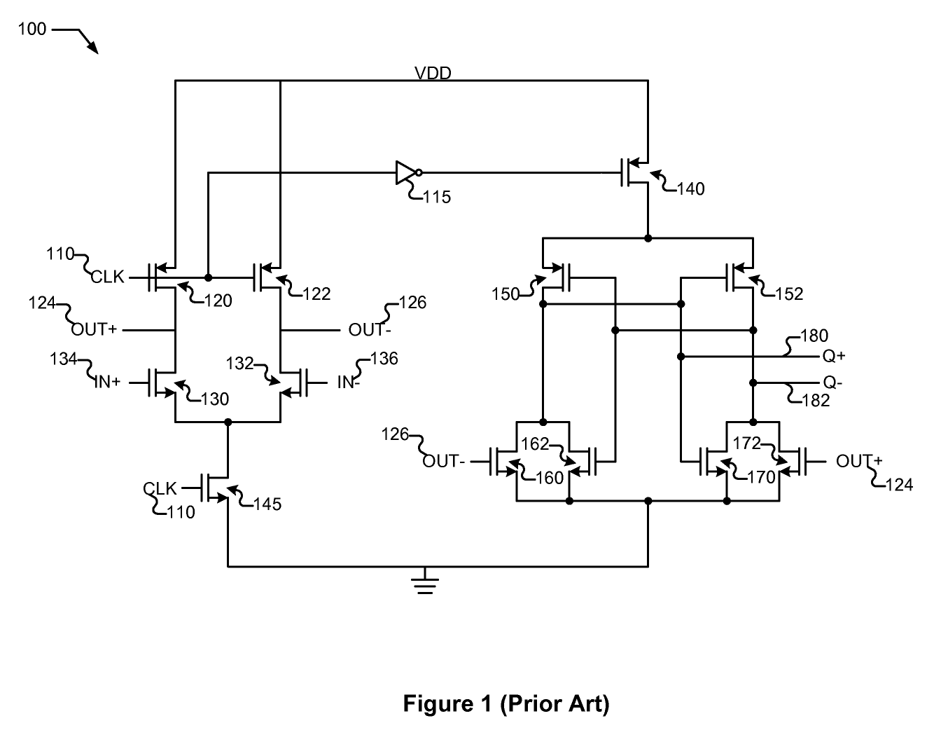

### DETAILED DESCRIPTION OF THE INVENTION

The present invention is related to systems, circuits and methods for comparing one input with another input.

Some embodiments of the present invention include a double input stage with one of the input stages designed to operate at low common mode input voltages, and the other input stage designed to operate at high common mode input voltages. Among other advantages, such an approach provides for an extended operational range of input signals. In some embodiments of the present invention, the input range is extended from approximately an upper rail (e.g., VDD) to approximately a lower rail (e.g., ground). Based on the disclosure provided herein, one of ordinary skill in the art will appreciate other advantages and/or input ranges that may be possible through use of one or more embodiments of the present invention.

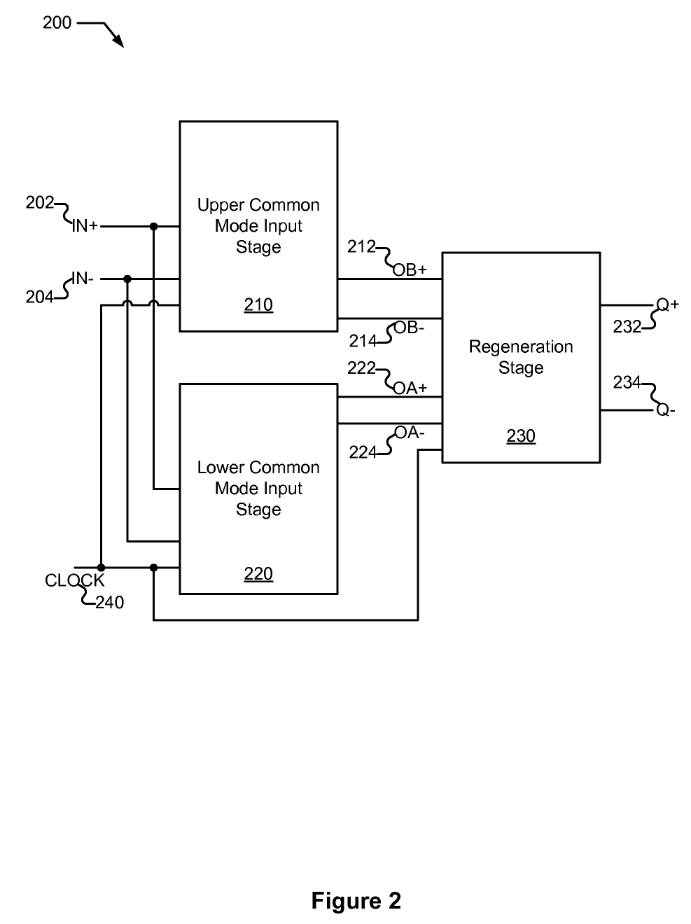

Turning to FIG. 2, a comparator system 200 exhibiting an extended input range is depicted in accordance with various embodiments of the present invention. Comparator system 200 includes an upper common mode input stage 210 and a lower common mode input stage 220 that each receive a positive input 202 (IN+) and a negative input 204 (IN−). A positive output 212 (OB+) and a negative output 214 (OB−) from upper common mode input stage 210 are provided to a regeneration stage 230. In addition, a positive output 222 (OA+) and a negative output 224 (OA−) from lower common mode input stage 220 are provided to regeneration stage 230. Regeneration stage 230 provides a positive output 232 (Q+) and a negative output 234 (Q−). Switching of comparator system 200 is done synchronous to a clock signal 240.

In operation, a first input signal is applied to positive input 202 and a second input signal is applied to negative input 204. A first differential output (i.e., positive output 212 (OB+) and negative output 214 (OB−)) reflecting the relative difference of positive input 202 and negative input 204 is provided by upper common mode input stage 210. The first differential input is not sensitive to situations where the common mode of positive input 202 and negative input 204 is high, and therefore may produce an undefined differential output where a relatively high common mode input exists. A second differential output (i.e., positive output 222 (OA+) and negative output 224 (OA−)) reflecting the relative difference of positive input 202 and negative input 204 is provided by lower common mode input stage 220. The second differential input is not sensitive to situations where the common mode of positive input 202 and negative input 204 is low, and therefore may produce an undefined differential output where a relatively low common mode input exists.

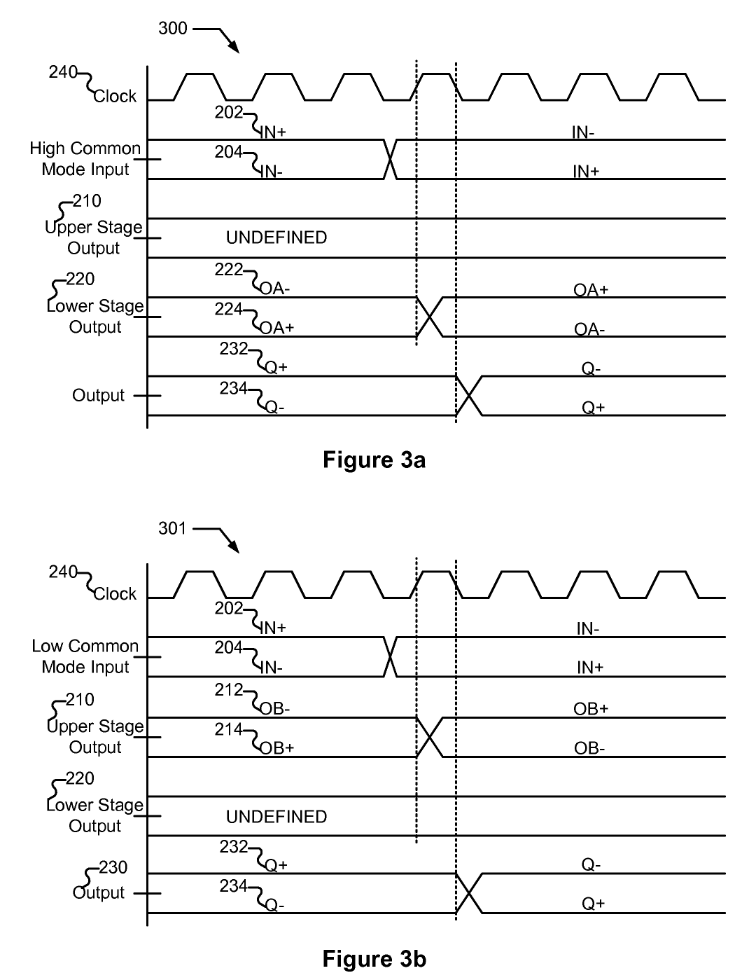

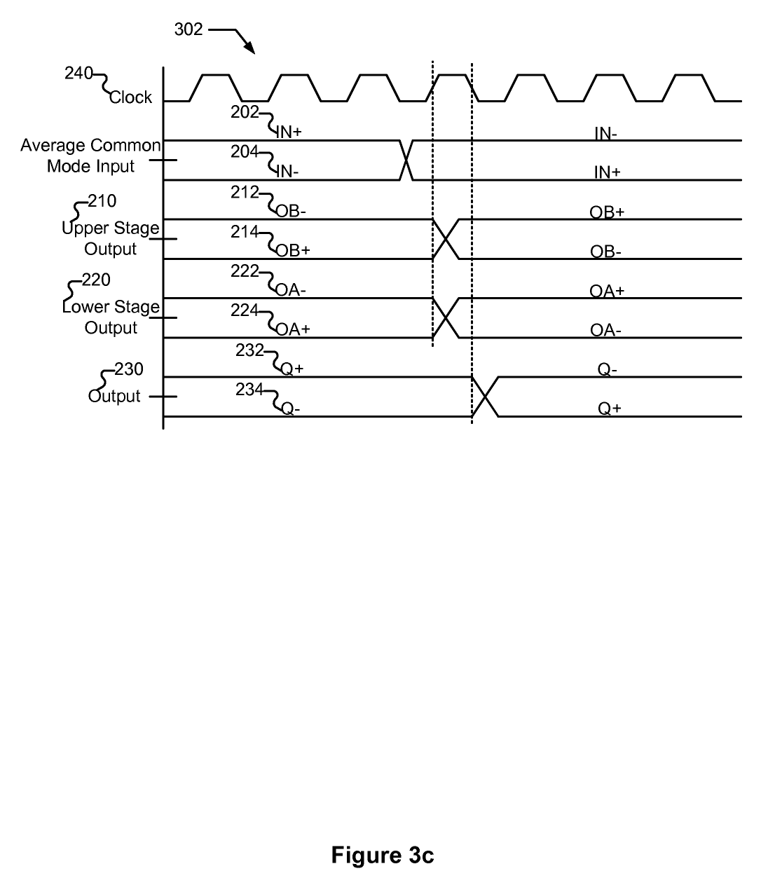

Regeneration stage 230 receives both the first differential output and the second differential output, discriminates between the two differential outputs, and produces positive output 232 and negative output 234 in a way that effectively eliminates the insensitivity to either a relatively high common mode input or a relatively low common mode input. Therefore, the difference between positive output 232 and negative output 234 will reflect the difference between positive input 202 and negative input 204 regardless of whether positive input 202 and negative input 204 exhibit either a high common mode or a low common mode. Hence, comparator system 200 is capable of comparing signals across an extended input range. Turning to FIG. 3a, operation of comparator system 200 is illustrated for a high common mode input using a timing diagram 300. As shown, positive input 202 and negative input 204 exhibits a high common mode resulting in an undefined output (i.e., positive output 212 and negative output 214) from upper common mode input stage 210, and a defined output (i.e., positive output 222 and negative output 224) from lower common mode input stage 220. The output from lower common mode input stage 220 switches on the positive edge of clock input signal 240, and the output of regeneration stage 230 switches on the subsequent negative edge of clock input signal 240 to reflect the output from lower common mode input stage 220. Of note, the output from regeneration stage 230 is governed by the output from lower common mode input stage 220 and not that from upper common mode input stage 210.

Turning to FIG. 3a, operation of comparator system 200 is illustrated for a high common mode input using a timing diagram 300. As shown, positive input 202 and negative input 204 exhibits a high common mode resulting in an undefined output (i.e., positive output 212 and negative output 214) from upper common mode input stage 210, and a defined output (i.e., positive output 222 and negative output 224) from lower common mode input stage 220. The output from lower common mode input stage 220 switches on the positive edge of clock input signal 240, and the output of regeneration stage 230 switches on the subsequent negative edge of clock input signal 240 to reflect the output from lower common mode input stage 220. Of note, the output from regeneration stage 230 is governed by the output from lower common mode input stage 220 and not that from upper common mode input stage 210.

Turning to FIG. 3b, operation of comparator system 200 is illustrated for a high common mode input using a timing diagram 301. As shown, positive input 202 and negative input 204 exhibits a low common mode resulting in an undefined output (i.e., positive output 222 and negative output 224) from lower common mode input stage 220, and a defined output (i.e., positive output 212 and negative output 214) from upper common mode input stage 210. The output from upper common mode input stage 210 switches on the positive edge of clock input signal 240, and the output of regeneration stage 230 switches on the subsequent negative edge of clock input signal 240 to reflect the output from upper common mode input stage 210. Of note, the output from regeneration stage 230 is governed by the output from upper common mode input stage 210 and not that from lower common mode input stage 220.

Turning to FIG. 3c, operation of comparator system 200 is illustrated for an average common mode input (i.e., a common mode input that is neither high nor low) using a timing diagram 302. As shown, positive input 202 and negative input 204 exhibits an average common mode resulting in a defined output (i.e., positive output 222 and negative output 224) from lower common mode input stage 220, and a defined output (i.e., positive output 212 and negative output 214) from upper common mode input stage 210. The output from upper common mode input stage 210 and the output from lower common mode input stage 220 both switch on the positive edge of clock input signal 240, and the output of regeneration stage 230 switches on the subsequent negative edge of clock input signal 240 to reflect the output from both upper common mode input stage 210 and lower common mode input stage. Of note, the output from regeneration stage 230 is governed by both the output from upper common mode input stage 210 and the output from lower common mode input stage 220.

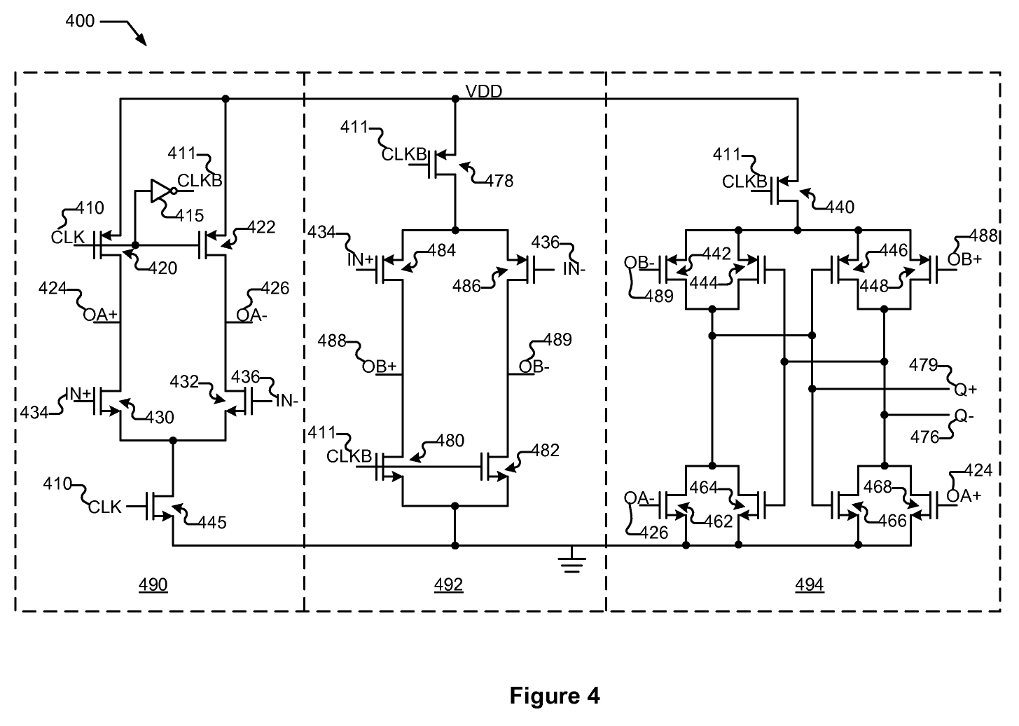

Turning to FIG. 4, an extended range comparator circuit 400 is depicted in accordance with various embodiments of the present invention. Extended range comparator circuit 400 includes an upper common mode input stage 492 (shown in dashed lines), a lower common mode input stage 490 (shown in dashed lines), and a regeneration circuit 494 (shown in dashed lines). Upper common mode input stage 492 receives a positive input 434 (IN+) and a negative input 436 (IN−), but is not sensitive to situations where the common mode of positive input 434 and negative input 432 is high, and therefore may produce an undefined differential output where a relatively high common mode input exists. Lower common mode input stage 490 receives positive input 434 and negative input 436, but is not sensitive to situations where the common mode of positive input 434 and negative input 432 is low, and therefore may produce an undefined differential output where a relatively low common mode input exists. Both of upper common mode input stage 492 and lower common mode input stage 490 are sensitive when the common mode of positive input 434 and negative input 432 is average.

As shown, lower common mode input stage 490 includes two N-type transistors 430, 432, two P-type transistors 420, 422, and an N-type transistor 445. The source of P-type transistor 420 and the source of P-type transistor 422 are electrically coupled to a power source (VDD). The gate of P-type transistor 420 and the gate of P-type transistor 422 are electrically coupled to a clock input signal 410. The drain of P-type transistor 420 is electrically coupled to the drain of N-type transistor 430, and the drain of P-type transistor 422 is electrically coupled to the drain of N-type transistor 432. The gate of N-type transistor 430 is electrically coupled to positive input 434 and the gate of N-type transistor 432 is electrically coupled to negative input 436. The source of N-type transistor 430 and the source of N-type transistor 432 are electrically coupled to the drain of N-type transistor 445. The gate of N-type transistor 445 is electrically coupled to clock input signal 410, and the source of N-type transistor 445 is electrically coupled to ground. Lower common mode input stage 490 provides a positive output 424 (OA+) from the drain of N-type transistor 430, and a negative output 426 (OA−) from the drain of N-type transistor 432. While not part of lower common mode input stage 490, clock input signal 410 is electrically coupled to an inverting buffer that produces an inverted clock input signal 411.

Upper common mode input stage 492 includes two P-type transistors 484, 486, two N-type transistors 480, 482, and a P-type transistor 478. The source of N-type transistor 480 and the source of N-type transistor 482 are electrically coupled to a ground. The gate of N-type transistor 480 and the gate of N-type transistor 482 are electrically coupled to inverted clock input signal 411. The drain of N-type transistor 480 is electrically coupled to the drain of P-type transistor 484, and the drain of N-type transistor 482 is electrically coupled to the drain of P-type transistor 486. The gate of P-type transistor 484 is electrically coupled to positive input 434 and the gate of P-type transistor 486 is electrically coupled to negative input 436. The source of P-type transistor 484 and the source of P-type transistor 486 are electrically coupled to the drain of P-type transistor 478. The gate of P-type transistor 478 is electrically coupled to inverted clock input signal 411, and the source of P-type transistor 478 is electrically coupled to a power source (VDD). Upper common mode input stage 492 provides a positive output 488 (OB+) from the drain of P-type transistor 484, and a negative output 489 (OB−) from the drain of P-type transistor 486.

Regeneration circuit 494 includes two P-type differential pairs each including two P-type transistors, and two N-type differential pairs each including two N-type transistors. A first N-type differential pair includes two N-type transistors 462, 464, and a second N-type differential pair includes two N-type transistors 466, 468. A first P-type differential pair includes two P-type transistors 442, 444, and a second P-type differential pair includes two P-type transistors 446, 448. In addition, regeneration circuit 494 includes a P-type transistor 440.

The gate of N-type transistor 462 is electrically coupled to negative output 426 from lower common mode input stage 490, and the gate of N-type transistor 464 is electrically coupled to positive output 424 from lower common mode input stage 490. The source of N-type transistor 462, the source of N-type transistor 464, the source of N-type transistor 466 and the source of N-type transistor 468 are electrically coupled to ground. The drain of N-type transistor 462 and the drain of N-type transistor 464 are electrically coupled to the drain of P-type transistor 442 and to the drain of P-type transistor 444. The drain of N-type transistor 466 and the drain of N-type transistor 468 are electrically coupled to the drain of P-type transistor 446 and to the drain of P-type transistor 448. The gate of N-type transistor 464 is electrically coupled to the gate of P-type transistor 444, and the gate of N-type transistor 466 is electrically coupled to the gate of P-type transistor 446. The gate of P-type transistor 442 is electrically coupled to negative output 489 from upper common mode input stage 492, and the gate of P-type transistor 448 is electrically coupled to positive output 488 from upper common mode input stage 492. The source of P-type transistor 442, the source of P-type transistor 444, the source of P-type transistor 446, and the source of P-type transistor are all electrically coupled to the drain of P-type transistor 440. The gate of P-type transistor 440 is electrically coupled to inverted clock input signal 411, and the source of P-type transistor 440 is electrically coupled to the power source (VDD). Regeneration stage 494 provides a positive output 474 (Q+) from the drains of P-type transistors 442, 444, and a negative output 476 (Q−) from the drains of P-type transistors 446, 448.

As used herein, the phrase “low common mode” is used in its broadest sense to mean an input value that is too low to render a circuit fully operational. Thus, as one example, in the case of lower common mode input stage 490, a common mode input may be defined by the following equation:

Common Mode=(IN+₄₃₄+IN−₄₃₆)/2.

In such a case, a low common mode input may be the aforementioned common mode that is insufficient to turn on one or both of N-type transistors 430, 432 when clock input signal 410 is asserted high. Also, as used herein, the phrase “high common mode” is used in its broadest sense to mean an input value that is too high to render a circuit fully operational. Thus, as one example, in the case of upper common mode input stage 492, a high common mode input may be the aforementioned common mode that is too high to turn on one or both of P-type transistors 484, 486 when inverted clock input signal 411 is asserted low. Additionally, as used herein, the phrase “average common mode” is used in its broadest sense to mean an input value that is sufficiently low and sufficiently high to render a circuit fully operational. Thus, as one example, in the case of lower common mode input stage 490 and upper common mode input stage 492, an average common mode input may be the aforementioned common mode that is sufficiently high to turn on one or both of N-type transistors 430, 432 and to cause transistor 445 to turn on when clock input signal 410 is asserted high, and it is sufficiently low to turn on one or both of P-type transistors 484, 486 and to cause transistor 478 to turn on when inverted clock input signal 411 is asserted low.

In operation, positive output 424 and negative output 426 are initially charged to approximately VDD when clock input signal 410 is asserted low. A first input is applied to positive input 434 and a second input is applied to negative input 436. When clock input 410 is asserted high, P-type transistors 420, 422 turn off, and N-type transistor 445 turns on causing positive output 424 and negative output 426 to discharge toward ground at a differential rate governed by the difference between positive input 434 and negative input 436. This combination of positive output 424 and negative output 426 is applied to regeneration circuit 494. Of note, where the common mode of positive input 434 and negative input 436 is low, lower common mode input stage 490 is not sensitive to the inputs as the potential on the inputs is insufficient to turn on two or more of N-type transistors 430, 432, 445.

Positive output 488 and negative output 489 are initially discharged to approximately ground when inverted clock input signal 411 is asserted high (i.e., clock input signal 410 is asserted low). Again, the first input is applied to positive input 434 and the second input is applied to negative input 436. When inverted clock input 411 is asserted low, N-type transistors 480, 482 turn off, and P-type transistor 478 turns on causing positive output 488 and negative output 489 to charge toward VDD at a differential rate governed by the difference between positive input 434 and negative input 436. This combination of positive output 488 and negative output 489 is applied to regeneration circuit 494. Of note, where the common mode of positive input 434 and negative input 436 is high, upper common mode input stage 492 is not sensitive to the inputs as the potential on the inputs is too high to turn on two or more of P-type transistors 484, 486, 478. Therefore, positive output 424 and negative output 426 reflect the difference between positive input 434 and negative input 436 whenever the common mode of positive input 434 and negative input 436 is not low, and positive output 488 and negative output 489 reflect the difference between positive input 434 and negative input 436 whenever the common mode of positive input 434 and negative input 436 is not high. In any event, at least one of positive output 424 and negative output 426 or positive output 488 and negative output 489 properly reflects the difference between positive input 434 and negative input 436 regardless of whether the common mode of positive input 434 and negative input 436 is high or low. Thus, the input range of comparator circuit 400 is extended.

Therefore, positive output 424 and negative output 426 reflect the difference between positive input 434 and negative input 436 whenever the common mode of positive input 434 and negative input 436 is not low, and positive output 488 and negative output 489 reflect the difference between positive input 434 and negative input 436 whenever the common mode of positive input 434 and negative input 436 is not high. In any event, at least one of positive output 424 and negative output 426 or positive output 488 and negative output 489 properly reflects the difference between positive input 434 and negative input 436 regardless of whether the common mode of positive input 434 and negative input 436 is high or low. Thus, the input range of comparator circuit 400 is extended.

When the common mode of positive input 434 and negative input 436 is low, positive output 424 and negative output 426 remain charged at about VDD. In contrast, positive output 488 and negative output 489 reflect the difference between positive input 434 and negative input 436. In such a situation, N-type transistors 462, 468 turn on, and P-type transistors 448, 442 turn on in proportion to the difference between positive output 488 and negative output 489 when inverted clock signal 411 is asserted low. This results in a differential across positive output 474 and negative output 476 that reflects the differential across positive input 434 and negative input 436. A positive feedback loop causes the differential across positive output 474 and negative output 476 to drive toward the rails (VDD and ground).

Alternatively, when the common mode of positive input 434 and negative input 436 is high, positive output 488 and negative output 489 remain discharged at about ground. Positive output 424 and negative output 426 reflect the difference between positive input 434 and negative input 436. In such a situation, P-type transistors 448, 442 turn on, and N-type transistors 466, 462 turn on in proportion to the difference between positive output 424 and negative output 426 when inverted clock signal 411 is asserted low. This results in a differential across positive output 474 and negative output 476 that reflects the differential across positive input 434 and negative input 436. A positive feedback loop causes the differential across positive output 474 and negative output 476 to drive toward the rails (VDD and ground).

As yet another alternative, when the common mode of positive input 434 and negative input 436 is average, the pair of positive output 488 and negative output 489 and the pair of positive output 424 and negative output 426 both reflect the difference between positive input 434 and negative input 436. In such a situation, the pair of P-type transistors 448, 442 and the pair of N-type transistors 466, 462 both turn on in proportion to the difference between positive input 434 and negative input 436 when inverted clock signal 411 is asserted low. This results in a differential across positive output 474 and negative output 476 that reflects the differential across positive input 434 and negative input 436. A positive feedback loop causes the differential across positive output 474 and negative output 476 to drive toward the rails (VDD and ground).

In conclusion, the invention provides novel systems, circuits, methods and arrangements for comparing input signals. While detailed descriptions of one or more embodiments of the invention have been given above, various alternatives, modifications, and equivalents will be apparent to those skilled in the art without varying from the spirit of the invention. For example, one or more embodiments of the present invention may be extended to compare more than two input signals. Therefore, the above description should not be taken as limiting the scope of the invention, which is defined by the appended claims.

1. A comparator circuit, the comparator circuit comprising:
a first input;
a second input;
a first input stage, wherein the first input stage receives the first input and the second input, wherein the first input stage is sensitive to a difference between the first input and the second input for at least a low common mode, and wherein the first input stage provides a first output synchronized to a prior edge of a clock signal;
a second input stage, wherein the second input stage receives the first input and the second input, wherein the second input stage is sensitive to a difference between the first input and the second input for at least a high common mode, and wherein the second input stage provides a second output synchronized to an edge of an inverted version of the clock signal; and
a regeneration stage, wherein the regeneration stage receives the first output and the second output, and wherein the regeneration stage is operable to provide a comparator output synchronized to a subsequent edge of the clock signal and reflecting the difference between the first input and the second input.

2. The comparator circuit of claim 1, wherein the first input stage includes a differential pair of P-type transistors, wherein the first input is electrically coupled to the gate of one of the P-type transistors of the differential pair, and wherein the second input is electrically coupled to the gate of another of the P-type transistors of the differential pair.

3. The comparator circuit of claim 1, wherein the second input stage includes a differential pair of N-type transistors, wherein the first input is electrically coupled to the gate of one of the N-type transistors of the differential pair, and wherein the second input is electrically coupled to the gate of another of the N-type transistors of the differential pair.

4. The comparator circuit of claim 1, wherein the first input stage includes:
a first N-type transistor;
a second N-type transistor;
a first P-type transistor;
a second P-type transistor; and
wherein the gate of the first N-type transistor and the gate of the second N-type transistor are electrically coupled to the clock signal, wherein the drain of the first N-type transistor is electrically coupled to the drain of the first P-type transistor and the drain of the second N-type transistor is electrically coupled to the drain of the second P-type transistor, and wherein the gate of the first P-type transistor is electrically coupled to the first input and the gate of second P-type transistor is electrically coupled to the second input.

5. The comparator circuit of claim 4, wherein the first input stage further includes:
a third P-type transistor, wherein the source of the first P-type transistor and the source of the second P-type transistor are electrically coupled to the drain of the third P-type transistor, wherein the gate of the third P-type transistor is electrically coupled to the clock signal, wherein the source of the third P-type transistor is electrically coupled to an upper rail, and wherein the source of the first N-type transistor and the source of the second N-type transistor are electrically coupled to a lower rail.

6. The comparator circuit of claim 5, wherein the first output includes a first positive output electrically coupled to the drain of the first P-type transistor and a first negative output electrically coupled to the drain of the second P-type transistor.

7. The comparator circuit of claim 1, wherein the second input stage includes:
a first N-type transistor;
a second N-type transistor;
a first P-type transistor;
a second P-type transistor; and
wherein the gate of the first P-type transistor and the gate of the second P-type transistor are electrically coupled to an inverted version of the clock signal, wherein the drain of the first P-type transistor is electrically coupled to the drain of the first N-type transistor and the drain of the second P-type transistor is electrically coupled to the drain of the second N-type transistor, and wherein the gate of the first N-type transistor is electrically coupled to the first input and the gate of second N-type transistor is electrically coupled to the second input.

8. The comparator circuit of claim 7, wherein the second input stage further includes:
a third N-type transistor, wherein the source of the first N-type transistor and the source of the second N-type transistor are electrically coupled to the drain of the third N-type transistor, wherein the gate of the third N-type transistor is electrically coupled to the clock signal, wherein the source of the third N-type transistor is electrically coupled to a lower rail, and
wherein the source of the first P-type transistor and the source of the second P-type transistor are electrically coupled to an upper rail.

9. The comparator circuit of claim 8, wherein the second output includes a second positive output electrically coupled to the drain of the first P-type transistor and a second negative output electrically coupled to the drain of the second P-type transistor.

10. The comparator circuit of claim 1, wherein the first output includes a first positive output and a first negative output, wherein the second output includes a second positive output and a second negative output, and wherein the regeneration stage includes:
a first, second, third and fourth N-type transistors;
a first, second, third, fourth and fifth P-type transistors;
wherein the gate of the first P-type transistor is electrically coupled to the first negative output, wherein the gate of the fourth P-type transistor is electrically coupled to the first positive output; wherein the gate of the first N-type transistor is electrically coupled to the second negative output, wherein the gate of the fourth N-type transistor is electrically coupled to the second positive output; wherein the gate of the second P-type transistor is electrically coupled to the gate of the second N-type transistor; wherein the gate of the third P-type transistor is electrically coupled to the gate of the third N-type transistor; wherein the drains of the first P-type transistor and the second P-type transistor are electrically coupled to the drains of the first N-type transistor and the second N-type transistor; wherein the drains of the third P-type transistor and the fourth P-type transistor are electrically coupled to the drains of the third N-type transistor and the fourth N-type transistor; wherein the comparator output is electrically coupled to nodes selected from a group consisting of: the gate of the second P-type transistor and the drain of the third P-type transistor, and the gate of the third P-type transistor and the drain of the second P-type transistor; and
wherein the source of the fifth P-type transistor is electrically coupled to an upper rail, wherein the drain of the fifth P-type transistor is electrically coupled to the source of the first P-type transistor, the second P-type transistor, the third P-type transistor and the fourth P-type transistor; and wherein the gate of the fifth P-type transistor is electrically coupled to the clock signal.

11. A mixed signal integrated circuit, the mixed signal integrated circuit comprising:
a differential analog input signal, wherein the differential analog input signal includes a first signal and a second signal;
a multiple input stage comparator, wherein the multiple input stage comparator includes:
a first input stage, wherein the first input stage receives the first signal and the second signal, wherein the first input stage is sensitive to a difference between the first signal and the second signal for at least a low common mode, and wherein the first input stage provides a first positive output and a first negative output each synchronized to a prior edge of a clock signal;
a second input stage, wherein the second input stage receives the first signal and the second signal, wherein the second input stage is sensitive to a difference between the first signal and the second signal for at least a high common mode, and wherein the second input stage provides a second positive output and a second negative output each synchronized to an edge of an inverted version of the clock signal; and
a regeneration stage, wherein the regeneration stage receives the first positive output, the first negative output, the second positive output and the second negative output, and wherein the regeneration stage is operable to provide a comparator output synchronized to a subsequent edge of the clock signal and reflecting a relative difference of the first signal and the second signal.

12. The circuit of claim 11, wherein the comparator output includes a positive comparator output and a negative comparator output, and wherein the positive comparator output and the negative comparator output are selected from a group consisting of: approximately an upper rail and approximately a lower rail; and approximately the lower rail and approximately the upper rail.

13. The circuit of claim 11, wherein the comparator output is a digital output, and wherein the digital output switches between approximately an upper rail and a lower rail.

14. The circuit of claim 11, wherein:
the first input stage includes:
a first N-type transistor;
a second N-type transistor;
a first P-type transistor;
a second P-type transistor; and
wherein the gate of the first N-type transistor and the gate of the second N-type transistor are electrically coupled to the clock signal, wherein the drain of the first N-type transistor is electrically coupled to the drain of the first P-type transistor and the drain of the second N-type transistor is electrically coupled to the drain of the second P-type transistor, and wherein the gate of the first P-type transistor is electrically coupled to the first signal and the gate of second P-type transistor is electrically coupled to the second signal;
the second input stage includes:
a third N-type transistor;
a fourth N-type transistor;
a third P-type transistor;
a fourth P-type transistor; and
wherein the gate of the third P-type transistor and the gate of the fourth P-type transistor are electrically coupled to an inverted version of the clock signal, wherein the drain of the third P-type transistor is electrically coupled to the drain of the third N-type transistor and the drain of the fourth P-type transistor is electrically coupled to the drain of the fourth N-type transistor, and wherein the gate of the third N-type transistor is electrically coupled to the first signal and the gate of fourth N-type transistor is electrically coupled to the second signal.

15. The circuit of claim 14, wherein the regeneration stage includes:
a fifth, sixth, seventh and eighth N-type transistors;
a fifth, sixth, seventh, eighth and ninth P-type transistors;
wherein the gate of the fifth P-type transistor is electrically coupled to the first negative output, wherein the gate of the eighth P-type transistor is electrically coupled to the first positive output; wherein the gate of the fifth N-type transistor is electrically coupled to the second negative output, wherein the gate of the eighth N-type transistor is electrically coupled to the second positive output; wherein the gate of the sixth P-type transistor is electrically coupled to the gate of the sixth N-type transistor; wherein the gate of the seventh P-type transistor is electrically coupled to the gate of the seventh N-type transistor; wherein the drains of the fifth P-type transistor and the sixth P-type transistor are electrically coupled to the drains of the fifth N-type transistor and the sixth N-type transistor; wherein the drains of the seventh P-type transistor and the eighth P-type transistor are electrically coupled to the drains of the seventh N-type transistor and the eighth N-type transistor; wherein the comparator output is electrically coupled to nodes selected from a group consisting of: the gate of the sixth P-type transistor and the drain of the seventh P-type transistor, and the gate of the seventh P-type transistor and the drain of the sixth P-type transistor; and
wherein the source of the fifth P-type transistor is electrically coupled to an upper rail, wherein the drain of the fifth P-type transistor is electrically coupled to the source of the first P-type transistor, the second P-type transistor, the third P-type transistor and the fourth P-type transistor; and wherein the gate of the fifth P-type transistor is electrically coupled to the clock signal.

16. An electronic device, the electronic device comprising:
a circuit performing an electronic function, wherein the circuit includes at least one multiple input stage comparator circuit including:
a first input and a second input;
a first input stage, wherein the first input stage receives the first input and the second input, wherein the first input stage is sensitive to a difference between the first input and the second input for at least a low common mode, and wherein the first input stage provides a first positive output and a first negative output each synchronized to a prior edge of a clock signal;
a second input stage, wherein the second input stage receives the first input and the second input, wherein the second input stage is sensitive to a difference between the first input and the second input for at least a high common mode, and wherein the second input stage provides a second positive output and a second negative output each synchronized to an edge of an inverted version of the clock signal; and
a regeneration stage, wherein the regeneration stage receives the first positive output, the first negative output, the second positive output and the second negative output, and wherein the regeneration stage is operable to provide a comparator output synchronized to a subsequent edge of the clock signal and reflecting a relative difference of the first input and the second input.

17. The electronic device of claim 16, wherein the circuit is a mixed signal circuit, wherein the first input and the second input together form an analog differential pair, and wherein the comparator output is a digital output.

18. The electronic device of claim 16, wherein the first input stage includes a first differential pair of P-type transistors; wherein the first input is electrically coupled to the gate of a first of the P-type transistors of the first differential pair, wherein the second input is electrically coupled to the gate of a second of the P-type transistors of the first differential pair; wherein the first positive output is electrically coupled to the drain of the first of the P-type transistors and the first negative output is electrically coupled to the drain of the second of the P-type transistors; wherein the second input stage includes a second differential pair of N-type transistors; wherein the first input is electrically coupled to the gate of a first of the N-type transistors of the second differential pair, wherein the second input is electrically coupled to the gate of a second of the N-type transistors of the second differential pair; and wherein the second positive output is electrically coupled to the drain of the first of the N-type transistors and the second negative output is electrically coupled to the drain of the second of the N-type transistors.

19. The electronic device of claim 16, wherein the electronic device is selected from a group consisting of: a communication device, a hard disk drive, an audio player, and a video player.

20. The electronic device of claim 16, wherein the electronic function is selected from a group consisting of: a communication function, a data storage function, a audio record function, an audio play function, a video record function, and a video play function.
